(19) United States
(12) Patent Application Publication
(10) Pub. No.: US 2014/0267998 A1
(43) Pub. Date: Sep. 18, 2014

(54) FLEXIBLE CABLE AND LIQUID CRYSTAL DISPLAY APPARATUS HAVING THE SAME

(71) Applicant: Samsung Display Co., Ltd., Yongin-City (KR)

(72) Inventors: Duk-Hwan KANG, Asan-si (KR); Sung-Mu KIM, Ansan-si (KR); Je-Hyun MOON, Busan (KR); Geun-Kyu SONG, Cheonan-si (KR); Chul SHIN, Busan (KR); Seok-Kun YOON, Seoul (KR)

(73) Assignee: Samsung Display Co., Ltd., Yongin-City (KR)

(21) Appl. No.: 13/952,794

(22) Filed: Jul. 29, 2013

(30) Foreign Application Priority Data
Mar. 12, 2013 (KR) 10-2013-0025990

(51) Int. Cl. G02F 1/1333; H05K 1/02

(52) U.S. Cl. CPC G02F 1/133305; H05K 1/028
USPC 349/150; 174/254

(57) ABSTRACT

A flexible cable includes a base film including an insulation material; a plurality of conductive lines on a first surface of the base film and spaced apart from one another; a cover film on the first surface of the base film and overlapping the conductive lines; and a handling member on a second surface of the base film opposite to the first surface. A first portion of the handling member is rounded and a second portion of the handling member is bonded to the base film.

This application claims priority to Korean Patent Application No. 10-2013-0025990, filed on Mar. 12, 2013, and all the benefits accruing therefrom under 35 U.S.C. §119, the contents of which are incorporated by reference herein in their entireties.

### BACKGROUND

1. Field

Exemplary embodiments of the invention relate to a flexible cable and a liquid crystal display apparatus having the flexible cable. More particularly, exemplary embodiments of the invention relate to a flexible cable and a liquid crystal display apparatus having the flexible cable.

2. Description of the Related Art

Generally, a liquid crystal display apparatus is advantageous in the dimension, weight and the power consumption thereof, so that the liquid crystal display apparatus is used in a monitor, a laptop computer, a cellular phone, a television and so on.

The liquid crystal display apparatus includes a display unit displaying an image, a control printed circuit board controlling a driving of the display unit and a flexible cable electrically connecting the display unit and the control printed circuit board.

The number of output signals outputted from the control printed circuit board is increased in compliance with many functions of a liquid crystal display apparatus. In addition, the number of conductive lines transferring the output signals to the display unit is increased and a space between the conductive lines is decreased. Accordingly, the flexible cable may be easily damaged in the process of manufacturing the liquid crystal display apparatus.

### SUMMARY

One or more exemplary embodiment of the invention provides a flexible cable having a modified grip part capable of reducing or effectively preventing damage to the flexible cable.

One or more exemplary embodiment of the invention further provides a liquid crystal display apparatus having the flexible cable.

According to an exemplary embodiment of the invention, a flexible cable includes a base film including an insulation material, a plurality of conductive lines provided on a first surface of the base film and spaced apart from one another, a cover film disposed on the first surface of the base film and overlapping the conductive lines, and a handling member which is partially bonded to a second surface of the base film opposite to the first surface and includes a rounded planar shape.

In an embodiment, the flexible cable may further include a guide line which is provided on the handling member and guides an engagement position of the flexible cable with an external connector.

In an embodiment, the guide line may include a color ink or a color tape.

In an embodiment, the handling member may further include a bonding part bonded to the second surface of the base film and configured to be partially inserted into an external connector, and a grip part integral with the bonding part and extending in a direction away from the base film.

In an embodiment, the grip part may have a rectangular shape of which a corner is rounded in a plan view.

In an embodiment, the grip part may have a half circular shape in a plan view.

In an embodiment, the grip part may have a half oval shape in a plan view.

In an embodiment, the grip part may have a triangle shape of which a corner is rounded in a plan view.

In an embodiment, the handling member may include at least one of a poly vinyl chloride (“PVC”), a polyethylene terephthalate (“PET”), a polycarbonate (“PC”), etc. These may be used alone or in a mixture thereof.

According to another exemplary embodiment of the invention, a liquid crystal display apparatus includes a liquid crystal panel displaying an image, a driving part which is connected with the liquid crystal panel and transfers a driving signal to the liquid crystal panel, a plurality of printed circuit boards which is connected with the driving part and transfers a control signal to the driving part, and a flexible cable which electrically connects a first printed circuit board and a second printed circuit board to each other and includes a handling member including a rounded planar shape.

In an embodiment, a printed circuit board may include a connector configured to be connected with the flexible cable.

In an embodiment, the flexible cable may further include a guide line which is on the handling member and guides an engagement position of the flexible cable with the connector.

In an embodiment, the guide line may include a color ink or a color tape.

In an embodiment, guide line may lengthwise extend in a same direction as a length of the connector.

In an embodiment, the flexible cable may further include a base film. The handling member may include a bonding part bonded to a second surface of a base film and configured to be partially inserted into an external connector, and a grip part integral with the bonding part and extending in a direction away from the base film.

In an embodiment, the grip part may have a rectangular shape of which a corner is rounded in a plan view.

In an embodiment, the grip part may have a half circular shape in a plan view.

In an embodiment, the grip part may have a half oval shape in a plan view.

In an embodiment, the grip part may have a triangle shape of which a corner is rounded in a plan view.

In an embodiment, the handling member may include at least one of a PVC, PET and a PC, etc. These may be used alone or in a mixture thereof.

According to one or more exemplary embodiment, the flexible cable includes the grip part having a rounded planar shape. Thus, in a process of inserting the flexible cable into the connector, the defect such as a scratch or damage to the flexible cable may be decreased.

In addition, the defect such as a scratch or damage to the flexible cable may be decreased, so that a quality of the display apparatus may be improved.

### BRIEF DESCRIPTION OF THE DRAWINGS

Exemplary embodiments of the invention can be understood in more detail from the following detailed description when taken in conjunction with the accompanying drawings, in which:

FIG. 1 is an exploded perspective view illustrating an exemplary embodiment of a liquid crystal display apparatus according to the invention;

FIG. 2 is a perspective view illustrating an exemplary embodiment of a flexible cable of the liquid crystal display apparatus in FIG. 1 according to the invention;

FIG. 3 is a cross-sectional view taken along line I-I′ of FIG. 2;

FIG. 4 is a plan view illustrating an exemplary embodiment of a flexible cable engaged with a connector of the liquid crystal display apparatus in FIG. 1 according to the invention;

FIG. 5 is a plan view illustrating an exemplary embodiment of a handling member of a flexible cable of the liquid crystal display apparatus in FIG. 1 according to the invention;

FIG. 6 is a plan view illustrating another exemplary embodiment of a handling member of a flexible cable of the liquid crystal display apparatus in FIG. 1 according to the invention;

FIG. 7 is a plan view illustrating still another exemplary embodiment of a handling member of a flexible cable of the liquid crystal display apparatus in FIG. 1 according to the invention;

FIG. 8 is a plan view illustrating yet another exemplary embodiment of a handling member of a flexible cable of the liquid crystal display apparatus in FIG. 1 according to the invention;

FIG. 9 is an exploded perspective view illustrating another exemplary embodiment of a liquid crystal display apparatus according to the invention;

FIG. 10 is an exploded perspective view illustrating still another exemplary embodiment of a liquid crystal display apparatus according to the invention;

FIG. 11 is a perspective view illustrating an exemplary embodiment of a flexible cable of the liquid crystal display apparatus in FIG. 10 according to the invention;

FIG. 12 is a cross-sectional view taken along line II-II′ of FIG. 11;

FIG. 13 is a plan view illustrating an exemplary embodiment of a flexible cable engaged with a connector of the liquid crystal display apparatus in FIG. 10 according to the invention;

FIG. 14 is a plan view illustrating an exemplary embodiment of a handling member of a flexible cable of the liquid crystal display apparatus in FIG. 10 according to the invention;

FIG. 15 is a plan view illustrating another exemplary embodiment of a handling member of a flexible cable the liquid crystal display apparatus in FIG. 10 according to the invention;

FIG. 16 is a plan view illustrating still another exemplary embodiment of a handling member of a flexible cable the liquid crystal display apparatus in FIG. 10 according to the invention; and

FIG. 17 is a plan view illustrating yet another exemplary embodiment of a handling member of a flexible cable the liquid crystal display apparatus in FIG. 10 according to the invention.

### DETAILED DESCRIPTION

It will be understood that when an element or layer is referred to as being “on,” “connected to” or “coupled to” another element or layer, the element or layer can be directly on, connected or coupled to another element or layer or intervening elements or layers. In contrast, when an element is referred to as being “directly on,” “directly connected to” or “directly coupled to” another element or layer, there are no intervening elements or layers present. As used herein, connected may refer to elements being physically and/or electrically connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “under” relative to other elements or features would then be oriented “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

A liquid crystal display apparatus includes a display unit displaying an image, a control printed circuit board controlling a driving of the display unit and a flexible cable electrically connecting the display unit and the control printed circuit board to each other. The flexible cable may be easily damaged in a process of manufacturing the liquid crystal display apparatus.

In a process of manufacturing the liquid crystal display apparatus, the flexible cable is inserted into a connector on a printed circuit board, to be connected with the printed circuit board. The process of inserting the flexible cable into the connector is performed manually. However, a grip part of the flexible cable has a rectangular shape whose corner is sharp, so that flexible cable may be easily damaged in the process of manufacturing the liquid crystal display apparatus. Therefore, there remains a need for an improved flexible cable and method of manufacturing a liquid crystal display apparatus including the flexible cable.

Hereinafter, exemplary embodiments of the invention will be explained in detail with reference to the accompanying drawings.

FIG. 1 is an exploded perspective view illustrating an exemplary embodiment of a liquid crystal display apparatus according to the invention.

Referring to FIG. 1, a liquid crystal display apparatus 100 includes a liquid crystal panel assembly 130, a backlight assembly 150, a mold frame 160, a lower receiving container 170 and an upper receiving container 110.

The liquid crystal panel assembly 130 includes a liquid crystal panel 133, driving parts 134 and 135, a first printed circuit board 136 and a second printed circuit board 137. The liquid crystal panel 133 displays an image. The driving parts 134 and 135 are respectively disposed at an end of the liquid crystal panel 133 to drive the liquid crystal panel 133. The first printed circuit board 136 provides a driving signal and a control signal to the liquid crystal panel 133. The first printed circuit board 136 is connected with the liquid crystal panel 133 through the driving parts 134 and 135. The second printed circuit board 137 is connected with the first printed circuit board 136 through a flexible cable 200.

The liquid crystal panel 133 may include a first display panel 131, a second display panel 132 and a liquid crystal layer (not shown) disposed between the first display panel 131 and the second display panel 132.

The first display panel 131 may include one or more gate line, one or more data line, a pixel electrode and a thin film transistor. The thin film transistor is connected to the gate line and the data line. The pixel electrode is connected to the thin film transistor. A plurality of gate lines lengthwise extends in a first direction and is spaced apart from each other. A plurality of data lines lengthwise extends in a second direction crossing the first direction, and is spaced apart from each other. The pixel electrode is disposed in a pixel region of the liquid crystal panel 133. In one exemplary embodiment, a pixel regions may be defined by the gate lines and the data lines arranged in a matrix form, but the invention is not limited thereto or thereby. The thin film transistor is switched by the data line to transfer a signal of the data line to the pixel electrode.

The second display panel 132 may include a light blocking pattern, a red, green and blue (“RGB”) color filter pattern and a common electrode. The light blocking pattern blocks transmission of a light in a region of the liquid crystal panel 133 except for the pixel region. The RGB color filter pattern expresses a color light. The common electrode realizes an image.

The first display panel 131 and the second display panel 132 are spaced apart from each other in a cross-sectional direction. An optically anisotropic liquid crystal layer may be disposed between first display panel 131 and the second display panel 132, but the invention is not limited to the optically anisotropic liquid crystal layer.

The driving parts 134 and 135 include a gate driving part 134 and a source driving part 135. The gate driving part 134 is connected with the gate line to provide a driving signal and a control signal to the liquid crystal panel 133. The source driving part 135 is connected with the data line to provide a driving signal and a control signal to the liquid crystal panel 133. Where a single gate driving part and a single source driving part are indicated by 134 and 135, respectively, a plurality of the gate and source driving parts may be indicated by 134 and 135.

The first printed circuit board 136 may be disposed at an end of the liquid crystal panel 133. The first printed circuit board 136 may be connected with the liquid crystal panel 133 through the source driving part 135. A driving integrated circuit (“IC”) may be disposed at substantially a center of the source driving part 135, as indicated by the rectangular member shown on the source driving part 135 in FIG. 1. The driving IC drives the liquid crystal panel 133.

The first printed circuit board 136 is physically and/or electrically connected with the source driving part 135. A plurality of electronic components (not shown) generating a driving signal and a control signal is mounted on the first printed circuit board 136. The second printed circuit board 137 is adjacent to the first printed circuit board 136, in a direction away from the liquid crystal panel 133. The second printed circuit board 137 may be physically and/or electrically connected with the first printed circuit board 136 through the flexible cable 200. A plurality of electronic components (not shown) generating a driving signal and a control signal is mounted on the second printed circuit board 137. Accordingly, a driving signal and a control signal generated from the second printed circuit board 137 may be provided to the first printed circuit board 136 through the flexible cable 200. The driving signal and the control signal provided to the first printed circuit board 136 from the second printed circuit board 136 may be provided to the liquid crystal panel 133 through the source driving part 135.

The first printed circuit board 136 and the second printed circuit board 137 may be grounded to the receiving container member 110 and/or 170 to reduce or effectively prevent false operation of the liquid crystal display apparatus 100 by an undesirable electromagnetic wave interference. That is, the first printed circuit board 136 and/or the second printed circuit board 137 may be bent along the lower receiving container 170 to be disposed at a back surface of the lower receiving container 170 and the liquid crystal display apparatus 100. The lower receiving container 170 may include a metal material. Where the first and second printed circuit boards 136 and 137 are bent along the lower receiving container 170, the first printed circuit board 136 is engaged with a side wall of the lower receiving container 170 and the second printed circuit board 137 is engaged with the back surface of the lower receiving container 170, so that an extent of the grounding may be increased.

The first printed circuit board 136 and the second printed circuit board 137 are connected to each other by the flexible cable 200. In the illustrated exemplary embodiment, the flexible cable 200 may be a flexible flat cable (“FFC”). The flexible cable 200 may include a plurality of central conductive lines. The plurality of conductive lines may include a conductor material such as a copper and the like. The central conductive lines may include a first conductive line transferring a certain signal, a second conductive line transferring an operation voltage and a third conductive line performing a grounding function. The flexible cable 200 may further include an insulation film. The insulation film may include a flexible and insulating material, such as a polyethylene terephthalate (“PET”) and the like. The insulation film may be bonded to one side or both of opposing sides of the central conductive lines.

The flexible cable 200 may be connected with the first printed circuit board 136 and/or the second printed circuit board 137 by a connector. Alternatively, the flexible cable 200 may be connected with the first printed circuit board 136 and/or the second printed circuit board 137 by an anisotropic conductive film (“ACF”). In the illustrated exemplary embodiment, the flexible cable 200 is connected with the first printed circuit board 136 by the ACF, and the flexible cable 200 is connected with the second printed circuit board 137 by a connector 300, but the invention is not limited thereto.

The flexible cable 200 may be connected with the second printed circuit board 137 by the connector 300. The connector 300 may be mounted on the second printed circuit board 137. That is, a connecting part of the flexible cable 200 is inserted into the connector 300 to be connected with the second printed circuit board 137, since the flexible cable 200 is connected with the first printed circuit board 136 by the ACF. The driving signal and the control signal from the second printed circuit board 137 may be provided to the first printed circuit board 136 through the flexible cable 200 connected with the connector 300.

The flexible cable 200 is connected with the first printed circuit board 136 by the ACF. A certain conductive pattern may be disposed on the flexible cable 200 so that the flexible cable 200 is configured to be connected with the first printed circuit board 136. The certain conductive pattern on the flexible cable 200 may be connected with a plurality of pads disposed on the first printed circuit board 136 by the ACF. The ACF may include a plurality of conductive particles.

As described above, the flexible cable 200 is connected with the first printed circuit board 136 by the ACF, but the invention is not limited thereto. In an alternative exemplary embodiment, for example, the flexible cable 200 may be connected with the first printed circuit board 136 by a connector assembly.

The back light assembly 150 generating and providing a light to the liquid crystal panel 133 may be disposed under the liquid crystal panel 133 in the cross-sectional direction. The back light assembly 150 may include one or more light source unit 153, a light guide plate 152, a reflecting sheet 154 and a plurality of optical sheets 151.

The light source unit 153 may be disposed at a side of the light guide plate 152, such as facing a side surface thereof. The light source unit 153 may include one or more light source 153b generating and providing light, and one or more light source cover 153a covering the light source 153b. A linear light source, such as a cold cathode fluorescent lamp (“CCFL”) or a hot cathode fluorescent lamp (“HCFL”) may be used as the light source 153b. Alternatively, a point light source, such as a light emitting diode (“LED”) may be used as the light source 153b. The light source unit 153 may be disposed at a long side or a short side of the light guide plate 152. Alternatively, two light source units 153 may be respectively disposed at adjacent sides or facing (e.g., opposing) sides of the light guide plate 152. In the illustrated exemplary embodiment, a plurality of light source units 153 is respectively disposed at long sides of the light guide plate 152, which face each other.

The light guide plate 152 may be substantially rectangular-shaped, having two long sides and two short sides. The light guide plate 152 transfers a light from the light source unit 153 to the liquid crystal panel 133. The light guide plate 152 may include a material having a high reflective index and a high transmittance, such as polymethylmethacrylate (“PMMA”), polycarbonate (“PC”) or polyethylene (“PE”) and the like. These may be used alone or in a mixture thereof.

The reflecting sheet 154 may be disposed under the light guide plate 152. The reflecting sheet 154 reflects a light leaked downward from the light guide plate 152 and toward the light guide plate 152 in an upper direction of the liquid crystal display apparatus 100, so that a luminance may be improved and a light may be supplied uniformly. The reflecting sheet 154 may include a material having a high reflective index and a high elasticity, such as PET and the like.

The optical sheets 151 may be disposed on the light guide plate 152. The optical sheets 151 uniformly transfer a light from the light guide plate 152 to the liquid crystal panel 133. The optical sheets 151 may include a diffusion sheet, a prism sheet and a protecting sheet, but are not limited thereto or thereby. The optical sheets 151 may include a transparent resin, such as an acrylic resin, a polyurethane resin or a silicon resin.

The mold frame 160 may be a rectangular frame to receive the back light assembly 150 therein, such as at an open center area thereof. The mold frame 160 may include a synthetic resin having insulating characteristic.

The lower receiving container 170 may be disposed under the back light assembly 150. The lower receiving container 170 receives and supports the liquid crystal panel 133, the back light assembly 150 and the mold frame 160 in a receiving space defined therein. The lower receiving container 170 may include aluminum or an aluminum alloy. The first printed circuit board 136 may be engaged with an outer surface of a side wall of the lower receiving container 170. The second printed circuit board 137 may be engaged with a back surface of the lower receiving container 170. The lower receiving container 170 may include one or more side wall extending from a bottom plate, to form the receiving space.

The upper receiving container 110 is engaged with the lower receiving container 170 to receive a liquid crystal panel assembly 130 and the back light assembly 150 therebetween. The upper receiving container 110 defines a display region. In one exemplary embodiment, an open center area of the frame-shaped upper receiving container 110 may expose a display area or display screen of the liquid crystal panel 133 to define the display region. In one exemplary embodiment, the upper receiving container 110 may be engaged with the lower receiving container 170 by a hook, but the invention is not limited thereto.

FIG. 2 is a perspective view illustrating an exemplary embodiment of a flexible cable of the liquid crystal display apparatus in FIG. 1 according to the invention. FIG. 3 is a cross-sectional view taken along line I-I′ of FIG. 2. FIG. 4 is a plan view illustrating an exemplary embodiment of a flexible cable engaged with a connector of the liquid crystal display apparatus in FIG. 1 according to the invention. FIG. 5 is a plan view illustrating an exemplary embodiment of a handling member of a flexible cable of the liquid crystal display apparatus in FIG. 1 according to the invention.

Referring to FIGS. 1 to 5, the flexible cable 200 includes an insulation film member 210, a plurality of conductive lines 220, a guide line 230 and a handling member 240. While a conductive line is indicated by 220, more than one conductive line may be indicated by 220. The conductive lines 220 may collectively form a conductive line layer.

The conductive lines 220 may be disposed in the insulation film member 210, such as between insulation film layers thereof. The insulation film member 210 may include a flexible and insulating material, such as PET and the like. The conductive lines 220 transfers a control signal from the second printed circuit board 137 to the first printed circuit board 136. The conductive lines 220 may lengthwise extend in an extension direction, and be spaced apart from one another in a direction crossing the extension direction. The conductive lines 220 may include a metal material such as copper.

A lower part of the insulation film member 210 is shorter in a length direction than an upper part of the insulation film member 210, so that distal end portions of the conductive lines 220 may be exposed. The distal end portions of the conductive lines 220 of the flexible cable 200 are physically and/or electrically connected to conductive lines disposed on the second printed circuit board 137.

The guide line 230 is disposed on the upper part of the insulation film member 210 to guide an engagement position of the flexible cable 200 with the connector 300 disposed on the second printed circuit board 137. The guide line 230 may be disposed towards an end portion of the insulation film member 210 and lengthwise extends in a width direction of the insulation film member 210. The guide line 230 may include a color ink or a color tape. The guide line 230 and the guide part 244 may lengthwise extend substantially a whole of the width of the insulation film member 210 in the width direction, but the invention is not limited thereto or thereby.

A position of the guide line 230 on the upper part of the insulation film member 230 may be determined depending on a length of the portion of the flexible cable 200 which is inserted into the connector 300. A portion of the insulation film member 210 is inserted into the connector 300, and then is fixed at a position by a cover 310 of the connector 300. The guide line 230 is disposed at a position not overlapped (e.g., exposed) by the cover 310. By comparing the position of the guide line 230 with a position of the cover 310 of the connector 300, a locking state between the flexible cable 200 and the connector 300 may be checked and adjusted.

The handling member 240 includes an insulating material having flexibility. The flexible material may include, but is not limited to, poly vinyl chloride (“PVC”), poly vinylidene chloride (“PVDC”), PET, PC, etc. The handling member 240 may include a bonding part 242 and a grip part 244. The bonding part 242 and the grip part 244 are integral with each other, such as to form a single, unitary, indivisible handling member 240. The bonding part 242 is bonded to the upper part of the insulation film member 210. The grip part 244 extends in a direction away from the upper part of the insulation film member 210, such as inclined with respect to the upper part of the insulation film member 210.

In one exemplary embodiment of manufacturing the liquid crystal display apparatus 100, the flexible cable 200 is inserted manually into the connector 300 using the grip part 244. That is, a user may hold the grip part 244 to guide the flexible cable 200 into the connector 300. Since such an inserting step of the flexible cable 200 is performed manually, a defect such as a scratch or damage to the flexible cable 200 may occur due to a sharp profile or sharp edges grip part. However, according to an exemplary embodiment of the invention, the grip part 244 has a substantial rectangular shape with a corner that is rounded or chamfered, in a plan view. Specifically, the corners at the distal end of the grip part 244 have the rounded or chamfered shape. Thus, the defect such as a scratch or damage to the flexible cable 200 may be reduced or effectively prevented, so that a quality of the liquid crystal display apparatus 100 may be improved.

As illustrated in the exemplary embodiment, the flexible cable 200 has a single layer structure having one conductive line layer, but is not limited thereto. The flexible cable 200 may have a multiple layer structure having a plurality of conductive line layers.

FIG. 6 is a plan view illustrating another exemplary embodiment of a handling member of a flexible cable of the liquid crystal display apparatus in FIG. 1 according to the invention.

A flexible cable according to the exemplary embodiment in FIG. 6 is substantially the same as the flexible cable according to the previous exemplary embodiment of FIGS. 1 to 5 excepting for a handling member, and thus the same reference numerals will be used to refer to the same or like parts as those described in the previous exemplary embodiment of FIGS. 1 to 5 and any repetitive explanation concerning the above elements will be omitted.

Referring to FIG. 6, the grip part 244 of the flexible cable 200 has a half circular shape in a plan view. In one exemplary embodiment of manufacturing the liquid crystal display apparatus 100, the flexible cable 200 is inserted manually into the connector 300 using the grip part 244. Since the inserting of the flexible cable 200 is performed manually, a defect such as a scratch or damage to the flexible cable 200 may be generated by a sharp grip part. However, according to an exemplary embodiment of the invention, the grip part 244 has a half circular shape in a plan view, where edges are curved so as to not be sharp. Thus, the defect such as a scratch or damage to the flexible cable 200 may be decreased, so that a quality of the liquid crystal display apparatus 100 may be improved.

FIG. 7 is a plan view illustrating still another exemplary embodiment of a handling member of a flexible cable of the liquid crystal display apparatus in FIG. 1 according to the invention.

A flexible cable according to the exemplary embodiment in FIG. 7 is substantially the same as the flexible cable according to the previous exemplary embodiment of FIGS. 1 to 5 excepting for a handling member, and thus the same reference numerals will be used to refer to the same or like parts as those described in the previous exemplary embodiment of FIGS. 1 to 5 and any repetitive explanation concerning the above elements will be omitted.

Referring to FIG. 7, the grip part 244 of the flexible cable 200 has a substantially half oval shape in a plan view. Curved edges of the grip part 244 may meet such as at an apex or point. In one exemplary embodiment of manufacturing the liquid crystal display apparatus 100, the flexible cable 200 is inserted manually into the connector 300 using the grip part 244. Since, the inserting of the flexible cable 200 is performed manually, a defect such as a scratch or damage to the flexible cable 200 may be generated by a sharp grip part. However, according to an exemplary embodiment, the grip part 244 has a half oval shape in a plan view. Thus, the defect such as a scratch or damage to the flexible cable 200 may be decreased, so that a quality of the liquid crystal display apparatus 100 may be improved.

FIG. 8 is a plan view illustrating yet another exemplary embodiment of a handling member of a flexible cable of the liquid crystal display apparatus in FIG. 1 according to the invention.

A flexible cable according to the exemplary embodiment in FIG. 8 is substantially the same as the flexible cable according to the previous exemplary embodiment of FIGS. 1 to 5 excepting for a handling member, and thus the same reference numerals will be used to refer to the same or like parts as those described in the previous exemplary embodiment of FIGS. 1 to 5 and any repetitive explanation concerning the above elements will be omitted.

Referring to FIG. 8, the grip part 244 of the flexible cable 200 has a triangle shape in a plan view. Extension lines of substantially linear edges of the grip part 244 may meet each other such as at an apex or point of the triangle. In one exemplary embodiment of manufacturing the liquid crystal display apparatus 100, the flexible cable 200 is inserted manually into the connector 300 using the grip part 244. Since the inserting of the flexible cable 200 is performed manually, a defect such as a scratch or damage to the flexible cable 200 may be generated by a sharp grip part. However, the grip part 244 according to an exemplary embodiment of the invention has a triangle shape whose corner (e.g., apex) is rounded in a plan view. Thus, the defect such as a scratch or damage to the flexible cable 200 may be decreased, so that a quality of the liquid crystal display apparatus 100 may be improved.

FIG. 9 is an exploded perspective view illustrating another exemplary embodiment of a liquid crystal display apparatus according to the invention.

A liquid crystal display apparatus 1100 according to the illustrated exemplary embodiment is substantially the same as the liquid crystal display apparatus 100 according to the previous exemplary embodiment of FIG. 1 except for a first printed circuit board 1136 and a second printed circuit board 1137 connected by connectors 1300 and 1500, and thus any repetitive explanation concerning the above elements will be omitted.

The liquid crystal display apparatus 1100 includes a liquid crystal panel assembly 1130, a backlight assembly 1150, a mold frame 1160, a lower receiving container 1170 and an upper receiving container 1110. The liquid crystal panel assembly 1130 includes a liquid crystal panel 1133, driving parts 1134 and 1135, the first printed circuit board 1136 and the second printed circuit board 1137. The liquid crystal panel 1133 may include a first display panel 1131, a second display panel 1132 and a liquid crystal layer (not shown) disposed between the first display panel 1131 and the second display panel 1132. The back light assembly 1150 may include one or more light source unit 1153, a light guide plate 1152, a reflecting sheet 1154 and a plurality of optical sheets 1151. The light source unit 1153 may include one or more light source 1153b generating and providing light, and one or more light source cover 1153a covering the light source 1153b.

Referring to FIG. 9, a flexible cable 1200 may be connected with the first printed circuit board 1136 by a connector 1500. The connector 1500 may be mounted on the first printed circuit board 1136. That is, a connecting part of the flexible cable 1200 is inserted into the connector 1500 so that the flexible cable 1200 is connected with the first printed circuit board 1136. The driving signal and the control signal from the second printed circuit board 1137 may be provided to the first printed circuit board 1136 through the flexible cable 1200 connected with the connector 1500. The driving signal and the control signal provided to the first printed circuit board 1136 from the second printed circuit board 1137 may be provided to the liquid crystal panel 1133 through a source driving part 1135.

The grip part of the flexible cable 1200 according to the illustrated exemplary embodiment has a round shape in a plan view. In one exemplary embodiment of manufacturing the liquid crystal display apparatus 100, the flexible cable 1200 is inserted manually into the connectors 1300 and 1500 using the grip part. Because, the inserting of the flexible cable 1200 is performed manually, a defect such as a scratch or damage to the flexible cable 1200 may be generated by a sharp grip part. However, according to an exemplary embodiment, the grip part has a round shape in a plan view. Thus, generating the defect such as a scratch or damage to the flexible cable 1200 may be decreased, so that a quality of the display apparatus may be improved.

FIG. 10 is an exploded perspective view illustrating still another exemplary embodiment of a liquid crystal display apparatus according to the invention.

A liquid crystal display apparatus 2100 according to the illustrated embodiment is substantially the same as the liquid crystal display apparatus 100 according to the previous exemplary embodiment of FIG. 1 excepting for a flexible cable 2200, a first printed circuit board 2136 and a second printed circuit board 2137, and thus any repetitive explanation concerning the above elements will be omitted.

The liquid crystal display apparatus 2100 includes a liquid crystal panel assembly 2130, a backlight assembly 2150, a mold frame 2160, a lower receiving container 2170 and an upper receiving container 2110. The liquid crystal panel assembly 2130 includes a liquid crystal panel 2133, driving parts 2134 and 2135, the first printed circuit board 2136 and the second printed circuit board 2137. The liquid crystal panel 2133 may include a first display panel 2131, a second display panel 2132 and a liquid crystal layer (not shown) disposed between the first display panel 2131 and the second display panel 2132. The back light assembly 2150 may include one or more light source unit 2153, a light guide plate 2152, a reflecting sheet 2154 and a plurality of optical sheets 2151. The light source unit 2153 may include one or more light source 2153b generating and providing light, and one or more light source cover 2153a covering the light source 2153b.

Referring to FIG. 10, the first printed circuit board 2136 and the second printed circuit board 2137 are electrically connected with the source driving part 2135. The source driving part 2135 is disposed at a long side of the liquid crystal panel 2133. The second printed circuit board 137 is adjacent to the first printed circuit board 136 in a direction parallel to the long side of the liquid crystal panel 2133. A plurality of electronic components (not shown) generating a driving signal and a control signal is mounted on the first printed circuit board 2136 and the second printed circuit board 2137. In the illustrated exemplary embodiment, a control printed circuit board generating a driving signal and a control signal is omitted. A function of the control printed circuit board is integrated into the first printed circuit board 2136 and the second printed circuit board 2137. The flexible cable 2200 is disposed between the first printed circuit board 2136 and the second printed circuit board 2137, and connects the first printed circuit board 2136 and the second printed circuit board 2137 to each other.

The first printed circuit board 2136 and the second printed circuit board 2137 may be electrically connected to each other by the flexible cable 2200. In the illustrated exemplary embodiment, the flexible cable 2200 may be a flexible printed circuit (“FPC”). The flexible cable 2200 may include a flexible and insulating material, such as a polyimide and the like. The flexible cable 2200 may include a plurality of conductive lines disposed on a base film. The flexible cable 2200 may include a wiring pattern including the conductive lines and a connecting part connecting with an external apparatus (not shown). A first connector 300 on the first printed circuit board 2136 may connect the flexible cable 2220 to the first printed circuit board 2136. A second connector 300 on the second printed circuit board 2137 may connect the flexible cable 2220 to the second printed circuit board 2137.

FIG. 11 is a perspective view illustrating an exemplary embodiment of a flexible cable of the liquid crystal display apparatus in FIG. 10. FIG. 12 is a cross-sectional view taken along line II-II′ of FIG. 11. FIG. 13 is a plan view illustrating an exemplary embodiment of a flexible cable engaged with a connector of the liquid crystal display apparatus in FIG. 10 according to the invention. FIG. 14 is a plan view illustrating an exemplary embodiment of a handling member of a flexible cable according to the invention. Since ends of the flexible cable 2200 have substantially the same structure, the structure of only the end of the flexible cable 2220 connected to the second printed circuit board 2137 is described below.

Referring to FIGS. 11 to 14, the flexible cable 2200 includes a base film 2210, a plurality of conductive lines 2220, a cover film 2215, a guide line 2230 and a handling member 2240. While a conductive line is indicated by 2220, more than one conductive line may be indicated by 2220. The conductive lines 2220 may collectively form a conductive line layer. The guide line 2230 may lengthwise extend substantially a whole of the width of the base film 2210 in the width direction, and the grip part 2230 may extend less than the whole of the width of the base film 2210.

The conductive lines 2220 may be disposed on the base film 2210. The base film 2210 may include a flexible and insulating material, such as a polyimide and the like. At the end of the flexible cable 2200, the conductive lines 2220 may lengthwise extend in an extension direction and be spaced apart from each other in a direction crossing the extension direction. The conductive lines 2220 may include a metal material, such as a copper.

The cover film 2215 protects the conductive lines 2220 and is disposed on a first surface of the base film 2210. At the end of the flexible cable 2200, the cover film 2215 is shorter in the extension direction of the conductive lines 2220 than the base film 2210, so that distal ends of the conductive lines 2220 may be exposed. The distal ends of the conductive lines 2220 at a first end of the flexible cable 2200 are physically and/or electrically connected with conductive lines disposed on the first printed circuit board 2136, and the distal ends of the conductive lines 2220 at a second end of the flexible cable 2200 opposing the first end are physically and/or electrically connected with conductive lines disposed on the second printed circuit board 2137.

At each of the first and second ends of the flexible cable 2200, the guide line 2230 is disposed on a second surface of the base film 2210 opposing the first surface, and guides an engagement position of the flexible cable 2200 with the connector 2300 disposed on the first printed circuit board 2136 and the second printed circuit board 2137, respectively. The guide line 2230 may be disposed toward the end of the base film 2210 and lengthwise extends in a direction crossing the extension direction of the conductive lines 2220. The guide line 2230 may include a color ink or a color tape.

A position of the guide line 2230 may be determined depending on a length in the extension direction of the portion of the flexible cable 2200 which is inserted into the connector 2300. A portion of the base film 2210 is inserted into the connector 2300, and then is fixed at a position by a cover 2310 of the connector 2300. The guide line 2230 is disposed at a position not overlapped (e.g., exposed) by the cover 2310. By comparing the position of the guide line 2230 with a position of the cover 2310 of the connector 2300, a locking failure between the flexible cable 2200 and the connector 2300 may be decreased.

The handling member 2240 includes a material having flexibility. The handling member 2240 may include a bonding part 2242 and a grip part 2244. The bonding part 2242 and the grip part 2244 are integral with each other, such as to form a single, unitary, indivisible handling member 2240. The bonding part 2242 is bonded to the second surface of the base film 2210. The grip part 2244 extends in a direction away from the second surface of the base film 2210.

In one exemplary embodiment of manufacturing the liquid crystal display apparatus 2100, the flexible cable 2200 is inserted manually into the connector 2300 using the grip part 2244. Since, the inserting of the flexible cable 2200 is performed manually, a defect such as a scratch or damage to the flexible cable 2200 may be generated by a sharp grip part. However, according to an exemplary embodiment, the grip part 2244 has a substantial rectangular shape with a corner that is rounded or chamfered in a plan view. Specifically, the corners at the distal end of the grip part 244 have the rounded or chamfered shape. Thus, the defect such as a scratch or damage to the flexible cable 2200 may be decreased, so that a quality of the liquid crystal display apparatus 2100 may be improved.

As illustrated in the exemplary embodiment, the flexible cable 2200 has a single layer structure having one conductive line layer, but is not limited thereto. The flexible cable 2200 may have a multiple single layer structure having a plurality of conductive line layers.

FIG. 15 is a plan view illustrating another exemplary embodiment of a handling member of a flexible cable of the liquid crystal display apparatus in FIG. 10 according to the invention.

A flexible cable according to the exemplary embodiment in FIG. 15 is substantially the same as the flexible cable according to the previous exemplary embodiment of FIGS. 10 to 14 excepting for a handling member 2240, and thus the same reference numerals will be used to refer to the same or like parts as those described in the previous exemplary embodiment of FIGS. 10 to 14 and any repetitive explanation concerning the above elements will be omitted.

Referring to FIG. 15, the grip part 2244 of the flexible cable 2200 has a half circular shape in a plan view. In one exemplary embodiment of manufacturing the liquid crystal display apparatus 2100, the flexible cable 2200 is inserted manually into the connector 2300 using the grip part 2244. Since the inserting of the flexible cable 2200 is performed manually, a defect such as a scratch or damage to the flexible cable 2200 may be generated by a sharp grip part. However, according to an exemplary embodiment, the grip part 2244 has a half circular shape in a plan view. Thus, the defect such as a scratch or damage to the flexible cable 2200 may be decreased, so that a quality of the liquid crystal display apparatus 2100 may be improved.

FIG. 16 is a plan view illustrating still another exemplary embodiment of a handling member of a flexible cable of the liquid crystal display apparatus in FIG. 10 according to the invention.

A flexible cable according to the exemplary embodiment in FIG. 16 is substantially the same as the flexible cable according to the previous exemplary embodiment of FIGS. 10 to 14 excepting for a handling member 2240, and thus the same reference numerals will be used to refer to the same or like parts as those described in the previous exemplary embodiment of FIGS. 10 to 14 and any repetitive explanation concerning the above elements will be omitted.

Referring to FIG. 16, the grip part 2244 of the flexible cable 2200 has a basic rectangular shape with an end which is half circular in a plan view. In one exemplary embodiment of manufacturing the liquid crystal display apparatus 2100, the flexible cable 2200 is inserted manually into the connector 2300 using the grip part 2244. Since the inserting of the flexible cable 2200 is performed manually, a defect such as a scratch or damage to the flexible cable 2200 may be generated by a sharp grip part. However, according to an exemplary embodiment, the grip part 2244 has a rectangular shape with an end which is half circular in a plan view. Thus, the defect such as a scratch or damage to the flexible cable 2200 may be decreased, so that a quality of the liquid crystal display apparatus 2100 may be improved.

FIG. 17 is a plan view illustrating yet another exemplary embodiment of a handling member of a flexible cable of the liquid crystal display apparatus in FIG. 10 according to the invention.

A flexible cable according to the exemplary embodiment in FIG. 17 is substantially the same as the flexible cable according to the previous exemplary embodiment of FIGS. 10 to 14 excepting for a handling member 2240, and thus the same reference numerals will be used to refer to the same or like parts as those described in the previous exemplary embodiment of FIGS. 10 to 14 and any repetitive explanation concerning the above elements will be omitted.

Referring to FIG. 17, the grip part 2244 of the flexible cable 2200 has a substantial triangle shape with a rounded corner (e.g., apex) in a plan view. In one exemplary embodiment of manufacturing the liquid crystal display apparatus 100, the flexible cable 2200 is inserted manually into the connector 2300 using the grip part 2244. Since the inserting of the flexible cable 2200 is performed manually, a defect such as a scratch or damage to the flexible cable 2200 may be generated by a sharp grip part. However, according to an exemplary embodiment, the grip part 2244 has a triangle shape with a rounded corner in a plan view. Thus, the defect such as a scratch or damage to the flexible cable 2200 may be decreased, so that a quality of the liquid crystal display apparatus 2100 may be improved.

According to one or more exemplary embodiment, the flexible cable includes the grip part having a round shape or a round edge. Thus, in a process of inserting the flexible cable to the connector, the defect such as a scratch or damage to the flexible cable may be decreased.

In addition, the defect such as a scratch or damage to the flexible cable may be decreased, so that a quality of the display apparatus may be improved.

The foregoing is illustrative of the invention and is not to be construed as limiting thereof. Although a few exemplary embodiments of the invention have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific exemplary embodiments disclosed, and that modifies to the disclosed exemplary embodiments, as well as other exemplary embodiments, are intended to be included within the scope of the appended claims. The invention is defined by the following claims, with equivalents of the claims to be included therein.

What is claimed is:

1. A flexible cable comprising:
a base film comprising an insulation material;
a plurality of conductive lines on a first surface of the base film, and spaced apart from one another;
a cover film on the first surface of the base film and overlapping the conductive lines; and
a handling member which is partially bonded to a second surface of the base film opposite to the first surface, and comprises a rounded planar shape.

2. The flexible cable of claim 1, further comprising:
a guide line which is on the handling member and guides an engagement position of the flexible cable with an external connector.

3. The flexible cable of claim 2, wherein the guide line comprises a color ink or a color tape.

4. The flexible cable of claim 1, wherein the handling member further comprises:
a bonding part bonded to the second surface of the base film and configured to be partially inserted into an external connector; and
a grip part integral with the bonding part and extending in a direction away from the second surface of the base film.

5. The flexible cable of claim 4, wherein the grip part has a rectangular shape of which a corner is rounded in a plan view.

6. The flexible cable of claim 4, wherein the grip part has a half circular shape in a plan view.

7. The flexible cable of claim 4, wherein the grip part has a half oval shape in a plan view.

8. The flexible cable of claim 4, wherein the grip part has a triangle shape of which a corner is rounded in a plan view.

9. The flexible cable of claim 4, wherein the handling member further comprises at least one of a material selected from a poly vinyl chloride, a polyethylene terephthalate and a polycarbonate.

10. A liquid crystal display apparatus comprising:
a liquid crystal panel which displays an image;
a driving part which is connected with the liquid crystal panel and transfers a driving signal to the liquid crystal panel;
a plurality of printed circuit boards which is connected with the driving part and transfers a control signal to the driving part; and
a flexible cable which electrically connects a first printed circuit board and a second printed circuit board to each other, and comprises a handling member comprising a rounded planar shape.

11. The liquid crystal display apparatus of claim 10, wherein a printed circuit board comprises:
a connector configured to be connected with the flexible cable.

12. The liquid crystal display apparatus of claim 11, wherein the flexible cable further comprises:
a guide line which is on the handling member and guides an engagement position of the flexible cable with the connector.

13. The liquid crystal display apparatus of claim 12, wherein the guide line comprises a color ink or a color tape.

14. The liquid crystal display apparatus of claim 13, wherein the guide line lengthwise extends in a same direction as a length of the connector.

15. The liquid crystal display apparatus of claim 10, wherein
the flexible cable further comprises a base film, and
the handling member comprises:
a bonding part bonded to a second surface of the base film and configured to be partially inserted into an external connector; and
a grip part integral with the bonding part and extending in a direction away from the second surface of the base film.

16. The liquid crystal display apparatus of claim 15, wherein the grip part has a rectangular shape of which a corner is rounded in a plan view.

17. The liquid crystal display apparatus of claim 15, wherein the grip part has a half circular shape in a plan view.

18. The liquid crystal display apparatus of claim 15, wherein the grip part has a half oval shape in a plan view.

19. The liquid crystal display apparatus of claim 15, wherein the grip part has a triangle shape of which a corner is rounded in a plan view.

20. The liquid crystal display apparatus of claim 15, wherein the handling member further comprises at least one of a material selected from a poly vinyl chloride, a polyethylene terephthalate and a polycarbonate.
